(19) United States
(12) Patent Application Publication
(10) Pub. No.: US 2019/0035647 A1
(43) Pub. Date: Jan. 31, 2019

(54) SUBSTRATE PROCESSING DEVICE

(71) Applicant: ASM IP Holding B.V., Almere (NL)

(72) Inventors: Ju Il Lee, Chungcheongnam-do (KR); Hie Chul Kim, Gyeonggi-do (KR); Dae Youn Kim, Seo-gu (KR)

(21) Appl. No.: 16/039,938

(22) Filed: Jul. 19, 2018

(30) Foreign Application Priority Data
Jul. 31, 2017 (KR) 10-2017-0097136

(51) Int. Cl. H01L 21/67

(52) U.S. Cl. CPC H01L 21/67023; H01L 21/67126; H01L 21/67098

(57) ABSTRACT

Provided is a substrate-processing device capable of preventing a top lid from sagging downward by the own weight of the substrate-processing device and/or a vacuum suction force generated by a vacuum pump and/or thermal shock at high temperature process, in a chamber including a plurality of reactors. Also, provided is a rotating shaft for transferring a substrate between the plurality of reactors.

### CROSS-REFERENCE TO RELATED APPLICATION

This application claims the benefit of Korean Patent Application No. 10-2017-0097136, filed on Jul. 31, 2017, in the Korean Intellectual Property Office, the disclosure of which is incorporated herein in its entirety by reference.

### BACKGROUND

### 1. Field

One or more example embodiments relate to a substrate-processing device, and more particularly, to a substrate-processing device capable of preventing sagging or deformation of a top lid.

### 2. Description of the Related Art

Recently, many attempts have been made to increase productivity (the number of substrates that can be processed per unit time) in semiconductor manufacturing. For example, there is a method of reducing a processing time for treating chemicals on a substrate. However, there is a limitation in reducing the processing time because a minimum amount of time is required to induce a reaction between the chemicals on the substrate.

Another method is to develop a reactor optimized for the reaction. For example, in the case of an atomic layer deposition device, a reactor with minimal internal volume may be developed to realize a fast switching time between heterogeneous gases. However, there is a physical limit to reducing a reaction space because of the minimum space required for gas flow and exhaust.

Alternatively, a vacuum chamber having a plurality of reactors therein may be considered. For example, a vacuum chamber having at least two identical reactors therein may not only increase the number of processed substrates per unit time but also connect several vacuum chambers to a transfer chamber as needed, thereby overcoming physical limitations of shortening a processing time or reducing volumes of the reactors. However, in the case of the vacuum chamber having a plurality of reactors therein, as the size of the vacuum chamber increases, the weight of a chamber cover (top lid) constituting an upper portion of the chamber increases and the chamber cover is distorted by a vacuum force, which limits the number of reactors in the vacuum chamber. Also, the degree of distortion of the chamber cover is increased in a high-temperature process.

U.S. Pat. No. 6,949,204 employs a dual chamber cover structure to prevent covers of the vacuum chamber from being distorted by the vacuum force. However, in such a case, there is a problem that complexity of a chamber structure due to the addition of structures increases, and difficulty of operation/maintenance due to the increase in chamber weight increases. In particular, as the size of a substrate increases, the physical size and volume of internal reactors to accommodate the substrate also increase correspondingly, which is a major obstacle to increasing the number of internal reactors and also limits the design and operation of a device.

### SUMMARY

One or more example embodiments include a device for solving the above-mentioned problems. In particular, a device for solving distortion of a chamber cover is provided in a vacuum chamber including a plurality of reactors. Also, one or more example embodiments include a device for transferring a substrate between the plurality of reactors.

Additional aspects will be set forth in part in the description which follows and, in part, will be apparent from the description, or may be learned by practice of the presented example embodiments.

According to one or more example embodiments, a substrate-processing device includes a top lid; a chamber wall including a through-hole; a plurality of substrate supports arranged in the chamber wall; a driving shaft penetrating through the through-hole of the chamber wall and extending between the plurality of substrate supports; and a top lid support formed in a hollow of the driving shaft and penetrating through the through-hole to support the top lid.

The substrate-processing device may further include a first plate connected to the driving shaft; and a second plate connected to the top lid support. For example, the first plate may be movable, and the second plate may be fixed.

The substrate-processing device may further include a drive unit connected to the first plate and configured to move the driving shaft up and down. The substrate-processing device may further include a fixing shaft extending between the chamber wall and the second plate. The top lid support and the second plate may be fixed to the chamber wall by the fixing shaft.

The substrate-processing device may further include a first shielding unit configured to shield a space between the chamber wall and the driving shaft; and a second shielding unit configured to shield a space between the driving shaft and the second plate. For example, at least one of the first shielding unit and the second shielding unit may include a stretchable portion; and a rotation support portion connected to the stretchable portion and configured to facilitate rotation of the driving shaft.

According to one or more example embodiments, a substrate-processing device includes a top lid; a chamber wall including a through-hole; a plurality of substrate supports arranged in the chamber wall; a driving shaft penetrating through the through-hole of the chamber wall and extending between the plurality of substrate supports; a top lid support formed in a hollow of the driving shaft and penetrating through the through-hole to support the top lid; a first plate connected to the driving shaft; a second plate configured to fixedly support the top lid support; a first shielding unit disposed between the first plate and the chamber wall; a second shielding unit disposed between the second plate and the driving shaft; a fixing shaft extending from the chamber wall to the second plate; a first drive unit connected to the first plate and configured to move the driving shaft up and down; and a second drive unit configured to rotate the driving shaft.

According to one or more example embodiments, a substrate-processing device includes an inner space defined by a top lid and a chamber wall; an exhaust portion connected to the inner space; a plurality of substrate supports arranged in the inner space; a through-hole penetrating through a lower surface of the chamber wall and formed between the plurality of substrate supports; and a top lid support configured to support the top lid through the through-hole.

The substrate-processing device may further include a driving shaft configured to surround the top lid support through the through-hole; a rotating motor configured to rotate the driving shaft; and a lifting motor configured to lift the driving shaft.

The substrate-processing device may further include a substrate transfer rotating arm connected to one surface of the driving shaft.

The substrate-processing device may further include a first sealing portion configured to surround the driving shaft; a second sealing portion configured to surround the top lid support; a first bellows configured to connect the first magnetic sealing portion to the lower surface of the chamber wall; and a second bellows configured to connect the second magnetic sealing portion to a lower surface of the driving shaft, wherein the first magnetic sealing portion and the second magnetic sealing portion may isolate the driving shaft and the top lid support from the outside.

The substrate-processing device may further include a top lid support plate configured to support the top lid support; and at least one top lid support plate fixing shaft configured to support the top lid support plate on the lower surface of the chamber wall.

An upper surface of the top lid support, which is in contact with the top lid, may be curved.

The substrate-processing device may further include at least one top lid support frame, wherein the top lid support frame may be connected to the top lid support and is configured to support the top lid across the inner space.

The substrate-processing device may further include at least one elastic portion on at least one surface of the top lid support for supporting the top lid and the top lid support frame. The elastic portion may include a cap; and an elastic body. The elastic body may be implemented as at least one of a spring, fluid, and gas, or a combination thereof.

The substrate-processing device may further include a gas or fluid supply line connected to the elastic portion; and a pressure controller.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a cross-sectional view of a substrate-processing device according to example embodiments;

FIG. 2 is a cross-sectional view of a substrate-processing device according to other example embodiments;

FIG. 3 is a cross-sectional view of a substrate-processing device according to other example embodiments;

FIG. 4 is a cross-sectional view of a substrate-processing device according to other example embodiments;

FIGS. 5A and 5B are cross-sectional views of a substrate-processing device according to other example embodiments;

FIGS. 6A and 6B are perspective views of a substrate-processing device according to example embodiments;

FIG. 6C is a front view of the substrate-processing device of FIG. 6A;

FIG. 6D is a perspective view of the substrate-processing device of FIG. 6A;

FIG. 7 is a partial enlarged view of a substrate-processing device according to example embodiments;

FIG. 8 is a partial cross-sectional view of a substrate-processing device, to which a top lid support frame is added, according to example embodiments;

FIG. 9 is a top view of the substrate-processing device of FIG. 8; and

FIGS. 10 to 13 are cross-sectional views of a substrate-processing device according to other example embodiments.

### DETAILED DESCRIPTION

Hereinafter, one or more example embodiments will be described more fully with reference to the accompanying drawings.

In this regard, the present example embodiments may have different forms and should not be construed as being limited to the descriptions set forth herein. Rather, these example embodiments are provided so that this disclosure will be thorough and complete, and will fully convey the scope of the inventive concept to one of ordinary skill in the art.

The terminology used herein is for the purpose of describing particular embodiments and is not intended to limit the inventive concept. As used herein, the singular forms “a,” “an” and “the” are intended to include the plural forms as well, unless the context clearly indicates otherwise. It will be further understood that the terms “includes,” “comprises” and/or “including,” “comprising” used herein specify the presence of stated features, integers, steps, operations, members, components, and/or groups thereof, but do not preclude the presence or addition of one or more other features, integers, steps, operations, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Example embodiments will be described hereinafter with reference to the drawings in which example embodiments are schematically illustrated. In the drawings, for example, illustrated shapes may be deformed according to fabrication technology and/or tolerances. Thus, example embodiments should not be construed as limited to the particular shapes of regions illustrated herein but may be to include deviations in shapes that result from, for example, manufacturing.

Although a deposition device of a semiconductor or a display substrate is described herein as a substrate-processing device, it is to be understood that the present disclosure is not limited thereto. The substrate-processing device may be any device necessary for performing deposition of a material for forming a thin film, and may refer to a device in which a raw material for etching or polishing the material is uniformly supplied. Hereinafter, for convenience of description, it is assumed that the substrate-processing device is a semiconductor deposition device.

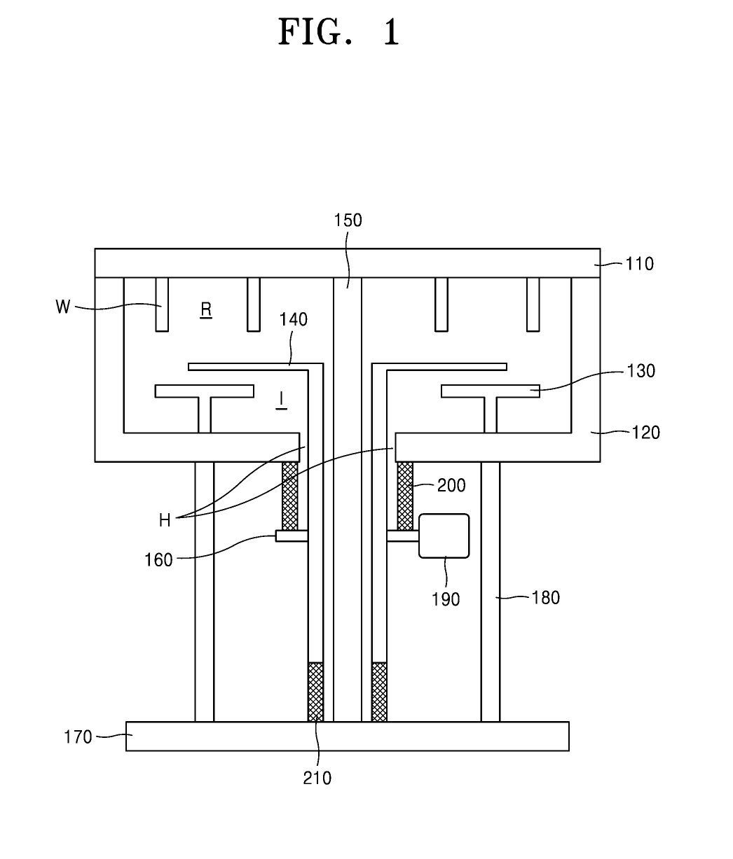

FIG. 1 is a cross-sectional view of a substrate-processing device according to example embodiments.

Referring to FIG. 1, the substrate-processing device may include a top lid 110, a chamber wall 120, a substrate support 130, a driving shaft 140, a top lid support 150, a first plate 160, a second plate 170, a fixing shaft 180, a drive unit 190, a first shielding unit 200, and a second shielding unit 210.

The top lid 110 functions as a lid of the substrate-processing device. For example, the top lid 110 may be provided with a reactor wall W and a gas supply (not shown). The gas supply (not shown) may be disposed in a reaction space R between reactor walls W. The gas supply may be implemented by, for example, a lateral flow-type assembly structure or a shower head-type assembly structure. The top lid 110 may be disposed at the top of the chamber wall 120.

An inner space I may be defined by the chamber wall 120 and the top lid 110. Also, in the inner space I, the reaction space R may be defined by the reactor wall W and the substrate support 130. The substrate-processing device may further include an exhaust portion (not shown) communicating with the internal space I and/or the reaction space R. A negative pressure may be generated in the inner space I and/or the reaction space R by an operation of the exhaust portion.

The chamber wall 120 may include a through-hole H. The through-hole H may be formed in a lower portion of the chamber wall 120. For example, the through-hole H may be formed at the center of the lower portion of the chamber wall 120. The through-hole H may be formed to extend from an inner lower surface of the chamber wall 120 to the inner space I.

The substrate support 130 may be disposed in the chamber wall 120. The substrate support 130 may be formed in the inner space I defined by the top lid 110 and the chamber wall 120. The substrate support 130 may be plural, so that the substrate-processing device may be configured to process a plurality of substrates simultaneously using the plurality of substrate supports 130. The through-hole H passing through the lower surface of the chamber wall 120 may be formed between the plurality of substrate supports 130.

The driving shaft 140 passes through the through-hole H of the chamber wall 120 and may extend between the plurality of substrate supports 130. The driving shaft 140 may be configured to be movable, for example, up and down and/or rotated. A substrate transfer rotating arm may be connected to one surface of the driving shaft 140. The driving shaft 140 may have a hollow structure. For example, the driving shaft 140 may be implemented as a rotating shaft rotatable with respect to the center of the hollow structure. The rotating shaft may pass through the through-hole H and surround the top lid support 150.

The top lid support 150 may be configured to support the top lid 110 through the through-hole H. The top lid support 150 may be formed in the hollow structure of the driving shaft 140. The top lid support 150 formed in the hollow structure of the driving shaft 140 may prevent the top lid 110 from being distorted by its own weight of the top lid 110 and/or by a negative pressure (namely, a vacuum suction force) of the inner space I generated by an evacuation portion such as a vacuum pump without affecting arrangement of components (e.g. the reactor walls W, the substrate supports 130, the driving shaft(s) 140, etc.) in the inner space I of the substrate-processing device and/or by thermal shock at high temperature process.

The first plate 160 is a movable component and may be connected to the driving shaft 140. The first plate 160 may transmit power of the drive unit 190 to the driving shaft 140 so that the driving shaft 140 may be moved up and down or rotate. For example, the first plate 160 may be moved up and down by the drive unit 190, and the driving shaft 140 connected to the first plate 160 may be moved up and down by the up and down movement of the first plate 160. As another example, the first plate 160 may be rotated by the drive unit 190, and the driving shaft 140 connected to the first plate 160 may be rotated by the rotation of the first plate 160.

The second plate 170 is a fixed component and may be connected to the top lid support 150. Thus, the top lid support 150 may be disposed between the top lid 110 and the second plate 170 to support the top lid 110. Further, the top lid support 150 may be fixedly supported by the second plate 170. That is, the second plate 170 may serve as a top lid support plate for supporting the top lid support 150.

The fixing shaft 180 may extend between the chamber wall 120 and the second plate 170. That is, the top lid support 150 and the second plate 170 may be fixed to the chamber wall 120 (and the lower surface thereof) by the fixing shaft 180 and the top lid support 150 of the second plate 170 may be fixedly supported.

The drive unit 190 may be connected to the first plate 160 which is movable to move the driving shaft 140. In an alternative example embodiment, the drive unit 190 may be configured to move the driving shaft 140 by being connected to the driving shaft 140 without passing through the first plate 160. For example, the drive unit 190 may include a rotating motor for rotating a rotating shaft of the driving shaft 140 and/or a lifting motor for lifting the driving shaft 140.

The first shielding unit 200 may shield a space between the chamber wall 120 and the driving shaft 140. The second shielding unit 210 may shield a space between the driving shaft 140 and the second plate 170. In an alternative embodiment, the first shielding unit 200 and/or the second shielding unit 210 may be configured not to prevent movement and/or rotation of the driving shaft 140 while preventing entry of external contaminants into the internal space I.

The first shielding unit 200 may be disposed between the chamber wall 120 and the first plate 160. In an alternative or additional example embodiment, the first shielding unit 200 may be disposed between the chamber wall 120 and the driving shaft 140. The second shielding unit 210 may be disposed between the driving shaft 140 and the second plate 170. In an alternative or additional example embodiment, the second shielding unit 210 may be disposed between the driving shaft 140 and the top lid support 150.

For example, the first shielding unit 200 may include at least one of a first sealing portion and a first stretchable portion. The first sealing portion may be a first magnetic sealing portion surrounding the driving shaft 140. The first magnetic sealing portion may isolate the inner space I from the outside. The first stretchable portion may include a first bellows that connects the first magnetic sealing portion to the lower surface of the chamber wall 120 (or connects the first magnetic sealing portion to the first plate 160).

The second shielding unit 210 may include at least one of a second sealing portion and a second stretchable portion. The second sealing portion may be a second magnetic sealing portion surrounding the top lid support 150. The second magnetic sealing portion may isolate the top lid support 150 and the inner space I to which the top lid support 150 is directed from the outside. The second stretchable portion may include a second bellows that connects the second magnetic seal portion to a lower surface of the driving shaft 140 (or connects the second magnetic seal portion to the second plate 170).

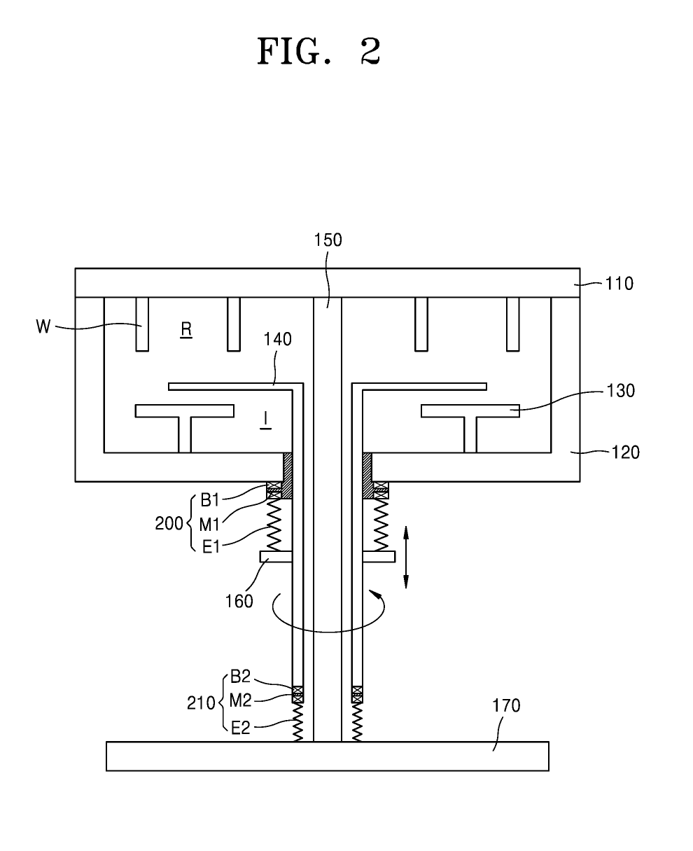

FIG. 2 is a cross-sectional view of a substrate-processing device according to other example embodiments. The substrate-processing device according to the example embodiments may be a variation of the substrate-processing device according to the above-described example embodiments. Hereinafter, repeated descriptions of the example embodiments will not be given herein.

Referring to FIG. 2, the first shielding unit 200 may include a first stretchable portion E1 and a first rotation support portion B1 and the second shielding unit 210 may include a second stretchable portion E2 and a second rotation support portion B2.

The first stretchable portion E1 may be disposed between the lower surface of the chamber wall 120 and the first plate 160 and may be stretched as the first plate 160 moves. For example, the first stretchable portion E1 may have a corrugated configuration (e.g., a bellows). When the first plate 160 and the driving shaft 140 connected to the first plate 160 move up, the first stretchable portion E1 may contract, and when the first plate 160 and the driving shaft 140 connected to the first plate 160 move down, the first stretchable portion E1 may expand.

In an alternative example embodiment, the first stretchable portion E1 may have elasticity. For example, the elasticity of the first stretchable portion E1 may be adjusted so as to be stretched or contracted in response to vertical movement of the driving shaft 140 so that shielding between the lower surface of the chamber wall 120 and the first plate 160 may be maintained.

The first stretchable portion E1 may include a first bellows that connects a first magnetic sealing portion M1 (or the first rotation support portion B1) to the lower surface of the chamber wall 120. The first magnetic sealing portion M1 may isolate the inner space I from the outside. For example, the first magnetic sealing portion M1 may be arranged to seal between the lower surface of the chamber wall 120 and the first rotation support portion B1 and/or between the first bellows and the first rotation support portion B1.

The first rotation support portion B1 may facilitate the rotation of the driving shaft 140. For example, the first rotation support portion B1 may be implemented as a bearing (e.g., a thrust bearing). In an alternative example embodiment, one end of the first rotation support portion B1 may be connected to the first stretchable portion E1 and the other end of the first rotation support portion B1 may be connected to the lower surface of the chamber wall 120. Also, in some example embodiments, the first magnetic sealing portion M1 may be disposed to be at least partially in contact with at least one of the driving shaft 140, the first stretchable portion E1, and the first rotation support portion B1.

The second stretchable portion E2 may be disposed between the lower surface of the driving shaft 140 and the second plate 170 and may expand or contract according to movement of the driving shaft 140. For example, the second stretchable portion E2 may have a corrugated configuration (e.g., a bellows). When the driving shaft 140 is moved up, the second stretchable portion E2 may expand, and when the driving shaft 140 is moved down, the second stretchable portion E2 may contract.

In an alternative example embodiment, the second stretchable portion E2 may have elasticity. For example, the elasticity of the second stretchable portion E2 may be adjusted so as to be stretched or contracted in response to vertical movement of the driving shaft 140 so that shielding between the lower surface of the driving shaft 140 and the second plate 170 may be maintained.

The second stretchable portion E2 may include a second bellows that connects a second magnetic sealing portion M2 (or the second rotation support portion B2) to the second plate 170. The second magnetic sealing portion M2 may isolate a space between the driving shaft 140 and the top lid support 150 (i.e., a space connected to the inner space I) from the outside. For example, the second magnetic sealing portion M2 may be disposed to seal between the lower surface of the driving shaft 140 and the second rotation support portion B2 and/or between the second bellows and the second rotation support portion B2.

The second rotation support portion B2 may facilitate the rotation of the driving shaft 140. For example, the second rotation support portion B2 may be implemented as a bearing (e.g., a thrust bearing). In an alternative example embodiment, one end of the second rotation support portion B2 may be connected to the second stretchable portion E2 and the other end of the second rotation support portion B2 may be connected to the driving shaft 140. Also in some example embodiments, the second magnetic sealing portion M2 may be disposed to be at least partially in contact with at least one of the driving shaft 140, the second stretchable portion E2, and the second rotation support portion B2.

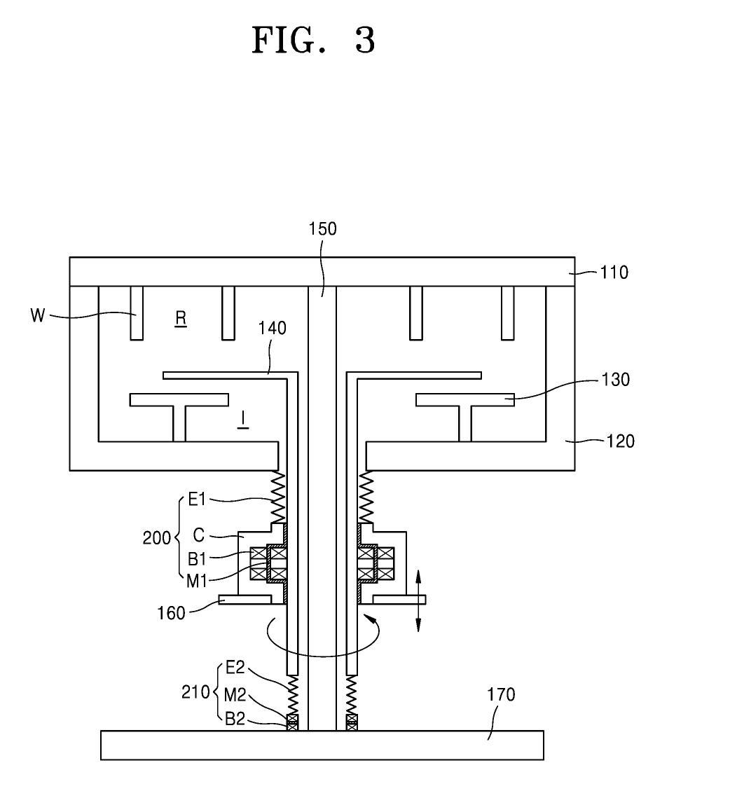

FIG. 3 is a cross-sectional view of a substrate-processing device according to other example embodiments. The substrate-processing device according to the example embodiments may be a variation of the substrate-processing device according to the above-described example embodiments. Hereinafter, repeated descriptions of the example embodiments will not be given herein.

Referring to FIG. 3, the first shielding unit 200 of the substrate-processing device may include the first stretchable portion E1, a housing C connected to the first stretchable portion E1, the first rotation support portion B1 disposed in the housing C, and the first magnetic sealing portion M1 for sealing the inner space I in contact with the first rotation support portion B1. The first rotation support portion B1, which is a radial bearing, may support the driving shaft 140 while maintaining/facilitating the rotation of the driving shaft 140. The first rotation support portion B1 may be implemented as a ball bearing, a roller bearing, or a fluid bearing, and may be implemented as any component that bears components while maintaining rotation. The first magnetic sealing portion M1 may function as a lubricating fluid of the first rotation support portion B1. In another example embodiment, the first rotation support portion B1 may be a fluid bearing, and the first magnetic sealing portion M1 may be a lubricating fluid of the fluid bearing.

The first plate 160 of the substrate-processing device may contact a lower surface of the housing C. Therefore, when the first plate 160 is moved up by a drive unit (not shown), the housing C that contacts the first plate 160 may be lifted. The first rotation support portion B1 and the driving shaft 140 may be moved up together with the lifting of the housing C.

The second stretchable portion E2 may include a second bellows that connects the second magnetic sealing portion M2 (or the second rotation support portion B2) to the driving shaft 140. That is, in the example embodiment of FIG. 2, the second rotation support portion B2 is disposed between the driving shaft 140 and the second stretching portion E2, while in the example embodiment of FIG. 3, the second rotation support portion B2 is disposed between the second stretching portion E2 and the second plate 170.

One end of the second rotation supporting portion B2 may be connected to the second stretching portion E2 and the other end of the second rotation supporting portion B2 may be connected to the second plate 170. In some example embodiments, the second magnetic sealing portion M2 may be disposed to be at least partially in contact with at least one of the driving shaft 140, the second stretchable portion E2, and the second rotation support portion B2. Accordingly, the second magnetic sealing portion M2 may isolate the space between the driving shaft 140 and the top lid support 150 (i.e., the space connected to the inner space I) from the outside.

In some example embodiments, the second rotation support portion B2 may be implemented as a ball bearing, a roller bearing, or a fluid bearing, and the second magnetic sealing portion M2 may function as a lubricating fluid of the second rotation support portion B2. In another example embodiment, the second rotation support portion B2 may be a fluid bearing, and the second magnetic sealing portion M2 may be a lubricating fluid of the fluid bearing.

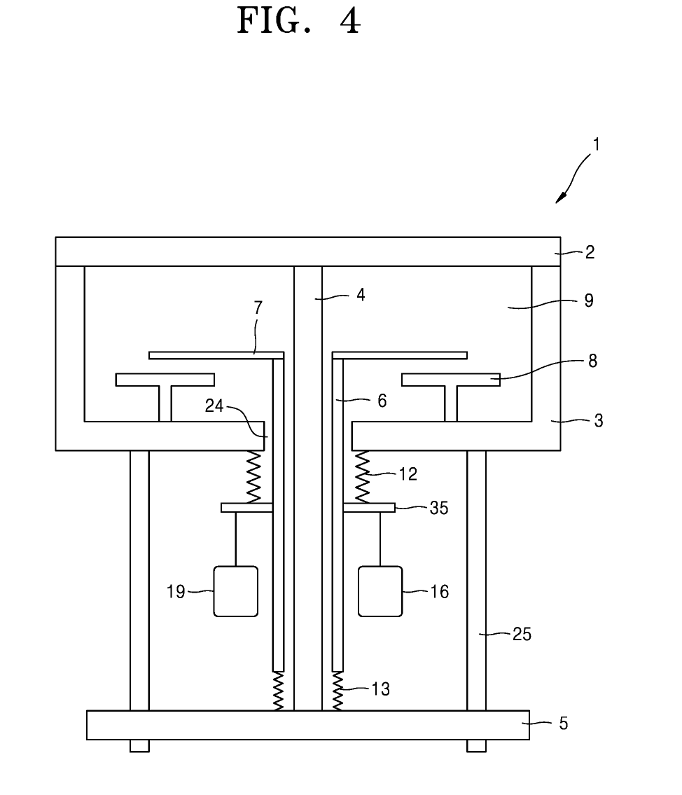

FIG. 4 is a cross-sectional view of a substrate-processing device according to other example embodiments.

Referring to FIG. 4, the substrate-processing device may include a chamber 1 including a top lid 2, a chamber wall 3, a plurality of substrate supports 8, a through-hole 24, a top lid support 4, a rotating shaft 6, a rotating motor 16, a lifting motor 19, a transfer arm 7, and a top lid support plate fixing shaft 25.

The top lid 2 and the chamber wall 3 may be brought into contact with each other to form an inner space 9. In more detail, the top lid 2 may be sealed with the chamber wall 3 on one side to form the inner space 9. A sealing member is inserted into the contact portion between the top lid 2 and the chamber wall 3 to prevent external gas from penetrating into the chamber 1 or gas in the chamber 1 from flowing out of the chamber 1. For example, an O-ring may be used as the sealing member to prevent gas infiltration/outflow or pressure rise.

The inner space 9 is connected to an exhaust device (not shown) and always maintains a lower pressure than the external atmosphere. The exhaust device may be, for example, an exhaust pump.

The plurality of (for example, two) substrate supports 8 may be arranged in the inner space 9. The substrate-processing device may simultaneously process a plurality of substrates in accordance with the number of the substrate supports 8.

A substrate support 8 may be arranged to correspond to a gas injection device (not shown), and may be configured to form a reaction space together with the gas injection devices. Further, the substrate support 8 may be configured to be capable of rotating and moving up and down (e.g., connected to a drive unit and a driving shaft). Each of a plurality of gas injection devices is disposed in the top lid 2 and may be disposed at a position corresponding to a corresponding substrate support 8 to form a reaction space together with the substrate support 8. The substrate support 8 and the gas injection device may contact each other to form a closed reaction space. Here, each reaction space may have an exhaust device. In another example embodiment, the substrate support 8 and the gas injection device do not contact each other and may form an open reaction space. Here, reaction gas may be exhausted through an exhaust device connected to the internal space 9.

The through-hole 24 is formed in a lower surface of the chamber wall 3 so as to penetrate through the lower surface of the chamber wall 3. The top lid support 4 extends through the through-hole 24 to the top lid 2. The top lid support 4 is formed in a columnar shape, and its horizontal section may have various shapes such as a circle, an ellipse, and a polygon.

The through-hole 24 may be formed between the plurality of substrate supports 8 and the top lid support 4 may extend between the plurality of substrate supports 8. The top lid support 4 supports the top lid 2 to prevent the top lid 2 from sagging downward by a vacuum suction force generated by a vacuum pump connected to the inner space 9 and/or its own weight of the top lid 2 and/or by a thermal shock at high temperature process. The top lid support 4 may have a length and a width that can prevent the top lid 2 from sagging downward by its own weight of the top lid 2 and/or by the vacuum suction force.

In an alternative example embodiment, the top lid support 4 is disposed so as to contact the inside of the top lid 2 rather than the edge of the top lid 2 in order to evenly distribute force for supporting the top lid 2 to the top lid 2. For example, the top lid support 4 may be disposed so as to be in contact with a center portion of the top lid 2.

The substrate-processing device may further include a top lid support plate 5 attached to the top lid support 4 to support the top lid support 4. For example, as shown in FIG. 4, the top lid support 4 may be connected to the top lid support plate 5 outside the chamber 1 through the through-hole 24.

The rotating shaft 6 may be disposed between the through-hole 24 and the top lid support 4. In particular, the rotating shaft 6 penetrates through the through-hole 24 and may be configured to surround the top lid support 4.

The transfer arm 7 for transferring a substrate may be disposed on and connected to the rotating shaft 6. The transfer arm 7 may include an end effector (not shown) on which a substrate is mounted. Substrates mounted on the transfer arm 7 may be introduced into the chamber 1 through a substrate entrance (not shown) on the side of the chamber wall 3 and may be mounted on the substrate support 8 corresponding to each gas injection device.

The rotating shaft 6 may be connected to the rotating motor 16 for rotating the rotating shaft 6. Furthermore, the rotating shaft 6 may be connected to the lifting motor 19 for lifting the rotating shaft 6. The rotating shaft 6 is rotatable by the rotating motor 16 and may be lifted by the lifting motor 19 to facilitate loading/unloading of the substrates between the transfer arm 7 and the substrate support 8.

A stretchable portion 13 may be disposed at a lower portion of the chamber 1 so that the rotating shaft 6 may be lifted. The stretchable portion 13 has a stretchable and contractible structure and may be made of a soft member so that the volume can be easily changed. For example, the stretchable portion 13 may be a bellows in which a corrugated portion is formed.

For example, as shown in FIG. 4, the stretchable portion 13 is disposed between the rotating shaft 6 and the top lid support plate 5 and may be stretched/contracted by the lifting of the rotating shaft 6. The stretchable portion 13 is formed so that resilience hardly acts, and it is possible to prevent a vertical position of the rotary shaft 6 from being changed by the resilience.

The stretchable portion 13 may be formed to surround the top lid support 4. A physical sealing device (for example, an O-ring) is inserted between the stretchable portion 13 and the rotating shaft 6 and between the stretchable portion 13 and the top lid support plate 5, and it is possible to prevent external gas from penetrating into the chamber 1 or gas in the chamber 1 from flowing out of the chamber 1.

An upper surface of the top lid support 4 and a lower surface of the top lid 2 are mechanically coupled to each other (for example, by friction between the upper surface of the top lid support 4 and the lower surface of the top lid 2 and/or by bolting between the top lid support 4 and the top lid 2) to fix the top lid support 4 to the top lid 2. However, when the rotating shaft 6 is lifted or rotated by the lifting motor 19 or the rotating motor 16, shaking occurs due to vibration, so that the top lid support plate 5 connected to the rotating shaft 6, and the top lid support 4 connected to the top lid support plate 5 may also be shaken.

In order to prevent this, the substrate-processing device according to the present disclosure may further include at least one top lid support plate fixing shaft 25 for fixing the top lid support plate 5 to the chamber wall 3. The top lid support 4 may also be fixed by holding the top lid support plate 5 on the top lid support plate fixing shaft 25, that is, by fixing the top lid support plate 5 to the chamber wall 3.

Although only one top lid support 4 is shown in FIG. 4, the top lid support 4 may be provided only at the center of the chamber 1, or may be provided at a plurality of positions (e.g., between substrate supports and/or between reaction spaces) at a plurality of lattice points. When a plurality of top lid supports are provided, the plurality of top lid supports may be arranged to minimize sagging of top lids without interfering with loading substrates.

In some example embodiments, a first stretchable portion 12 and the second stretchable portion 13 may be disposed under the chamber wall 3 so as to be able to move up and down the rotating shaft 6 and isolate the inner space 9 from the outside. The first stretchable portion 12 is disposed between the lower surface of the chamber wall 3 and a stretchable portion support plate 35 and is configured to surround the rotating shaft 6 so as to be stretched and contracted by lifting the rotating shaft 6. The second stretchable portion 13 is disposed between the rotating shaft 6 and the top lid support plate 5 and is configured to surround the top lid support 4 so as to be stretched/contracted by lifting the rotating shaft 6. A physical sealing device (e.g., an O-ring) or the like may be inserted between the first stretchable portion 12 and the chamber wall 3, between the first stretchable portion 12 and the stretchable portion support plate 35, between the second stretchable portion 13 and the rotating shaft 6, and between the second stretchable portion 13 and the top lid support plate 5 in order to further prevent external gas from penetrating into the chamber 1 or gas in the chamber 1 from flowing out of the chamber 1.

In an alternative example embodiment, the substrate-processing device according to the present disclosure may further include a sealing portion to maintain sealability between the rotating shaft 6 and the top lid support 4 and the external atmosphere. For example, the first sealing portion surrounding the rotating shaft 6 and/or the second sealing portion surrounding the top lid support 4 may be disposed.

The sealing portion may be a magnetic sealing portion. A seal material of the magnetic sealing portion is clean because it does not generate abrasive particles due to physical friction. The magnetic sealing portion which can be used in an extremely high vacuum area (10 Pa to 15 Pa) has a long lifetime because there is no abrasion loss due to solid friction and there is no loss torque and high speed rotation is possible since the magnetic sealing portion uses a liquid seal material. Also, the magnetic sealing portion does not affect rotation of the rotating shaft 6 because there is no contact load.

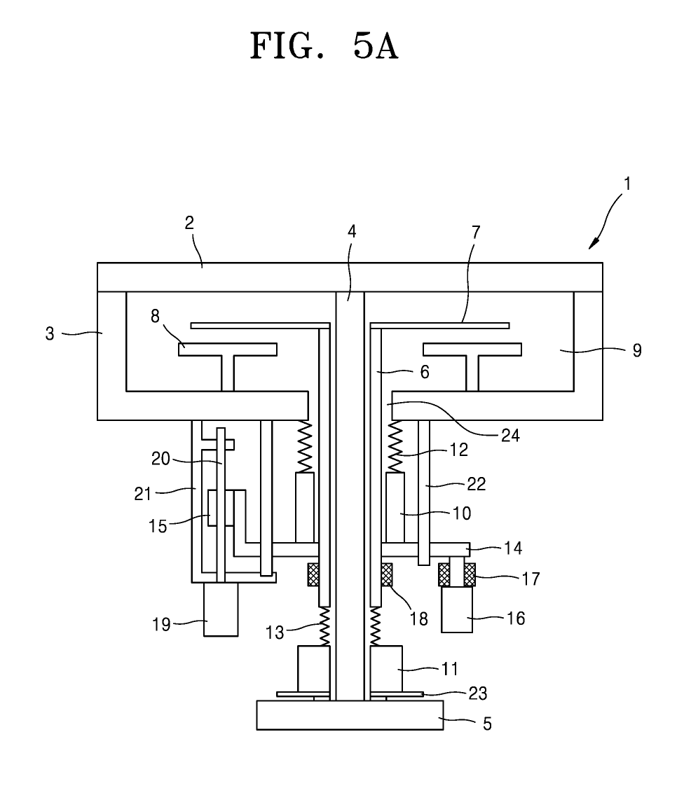

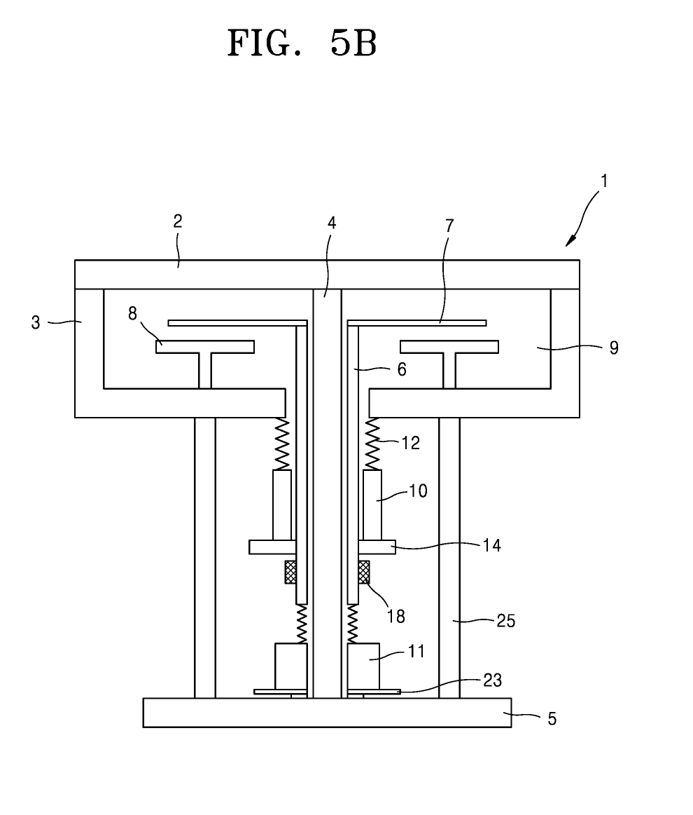

FIG. 5A is a cross-sectional view of a substrate-processing device according to other example embodiments. Hereinafter, repeated descriptions of the example embodiments will not be given herein.

Referring to FIG. 5A, the substrate-processing device may further include a lifting guide plate 20, a lifting guide fixing plate 21, a lifting sensor plate 15, a first rotation gear 17, a second rotation gear 18, and a rotation sensor plate 23.

The first stretchable portion 12 may connect a first sealing portion 10 to the chamber wall 3 and the second stretchable portion 13 may connect a second sealing portion 11 to the rotating shaft 6. The first sealing portion 10 may be disposed between the first stretchable portion 12 and a lifting plate 14 and may surround the rotating shaft 6. The second sealing portion 11 may be disposed between the second stretchable portion 13 and the top lid support plate 5 and may surround the top lid support 4.

When the first sealing portion 10 and/or the second sealing portion 11 is a magnetic sealing portion, each of the sealing portions includes a plurality of grooves in the inner surface contacting with the rotating shaft 6 and the top lid support 4, and a magnetic fluid may be supplied to the grooves. The magnetic fluid contacts the rotating shaft 6 and the top lid support 4 to isolate the inner space 9 of the chamber 1 from the external atmosphere. In particular, the magnetic fluid forms a kind of blocking film by magnetic force. As the rotating shaft 6 rotates, a magnetic substance covers the entire surface of the rotating shaft 6, and thus, contaminants from the outside do not flow into a vacuum portion of the chamber 1.

A physical sealing device (e.g., an O-ring) or the like may be inserted between the first stretchable portion 12 and the chamber wall 3, between the first stretchable portion 12 and the first sealing portion 10, between the second stretchable portion 13 and the second sealing portion 11, and between the second stretchable portion 13 and the rotating shaft 6 in order to further prevent external gas from penetrating into the chamber 1 or gas in the chamber 1 from flowing out of the chamber 1.

The second sealing portion 11 is divided into a drive unit and a non-drive unit, and the rotation sensor plate 23 may be disposed therebetween. The rotation sensor plate 23 may sense the degree of rotation of the rotating shaft 6.

The rotating shaft 6 is rotatable by the rotating motor 16, the first rotation gear 17, and the second rotation gear 18, and may be lifted by the lifting motor 19, the first stretchable portion 12, and the second stretchable portion 13 to facilitate loading/unloading of the substrates between the transfer arm 7 and the substrate support 8.

In more detail, the lifting and rotation of the rotating shaft 6 shown in FIG. 5A may be performed as follows.

First, the rotation of the rotating shaft 6 is performed as follows.

As shown in FIG. 5A, the rotating motor 16 is connected to the lifting plate 14, and the first rotation gear 17 may be disposed on one surface of the rotating motor 16. The second rotation gear 18 is disposed on one surface of the rotating shaft 6. Rotational power of the rotating motor 16 may be transmitted to the rotating shaft 6 by connecting the first rotation gear 17 to the second rotation gear 18 by a belt (not shown), thereby rotating the rotating shaft 6.

The drive unit of the second sealing portion 11 and the second stretchable portion 13 rotate together when the rotating shaft 6 rotates. As described above, a magnetic fluid is supplied between the first sealing portion 10 and the rotating shaft 6 and between the second sealing portion 11 and the top lid support 4 to block inflow of the external atmosphere when the rotating shaft 6 rotates, and airtightness of the inner space 9 of the chamber 1 may be maintained.

Next, the lifting of the rotating shaft 6 may be performed as follows.

As shown in FIG. 5A, the lifting motor 19 and the lifting guide plate 20 are fixed to the lifting guide fixing plate 21. The lifting motor 19 may transmit lifting driving force to the lifting guide plate 20. The lifting guide plate 20 may transmit the lifting driving force to the lifting sensor plate 15 and the lifting plate 14 to drive the lifting plate 14 in a vertical direction.

In an additional example embodiment, the lifting guide plate 20 and the lifting sensor plate 15 include a screw thread and may be engaged with each other to transmit driving force of the lifting motor 19. In another example embodiment, the lifting guide plate 20 includes a hydraulic system that transmits the driving force of the lifting motor 19 and may transmit the driving force of the elevating motor 19 to the lifting sensor plate 15 and the lifting plate 14.

The lifting sensor plate 15 is disposed on one side of the lifting plate 14 to define a range of vertical movement of the lifting plate 14.

In an additional example embodiment, a plurality of lifting plate guide shafts 22 may be disposed through the lifting plate 14. Here, the lifting plate 14 may be moved up and down along the lifting plate guide shafts 22 to perform reproducible lifting movement without departing from a lifting movement track.

FIG. 5B is a cross-sectional view of the substrate-processing device of FIG. 5A viewed from a different direction. In an example embodiment, FIG. 5B may be a view of the substrate-processing device of FIG. 5A viewed from a direction rotated by 90 degrees.

Referring to FIG. 5B, the top lid support plate 5 may be fixed to the chamber wall 3 by at least one top lid support plate fixing shaft 25. As described above, the top lid support 4, which is a rotation center of the rotating shaft 6, may be fixed by introducing the top lid support plate fixing shaft 25.

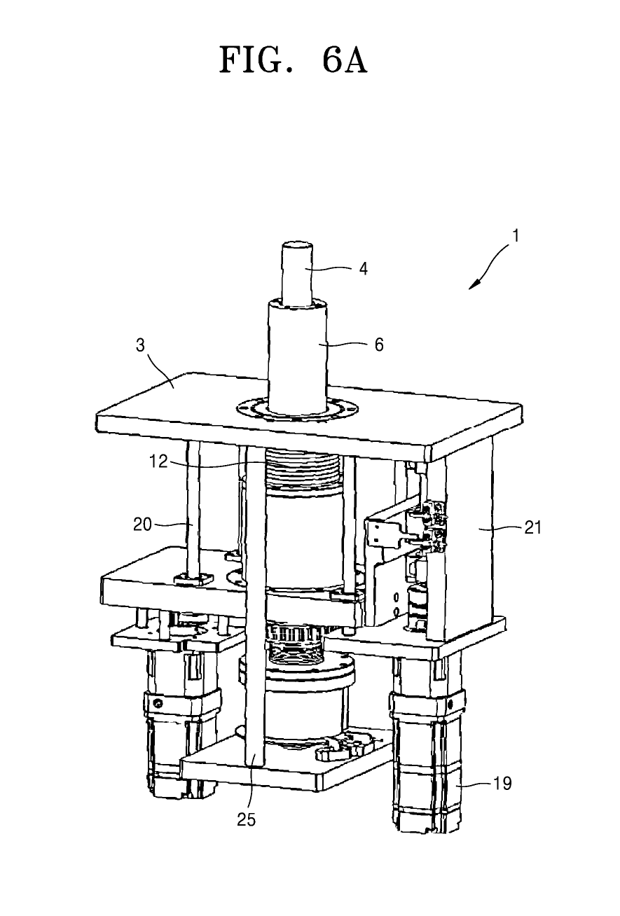

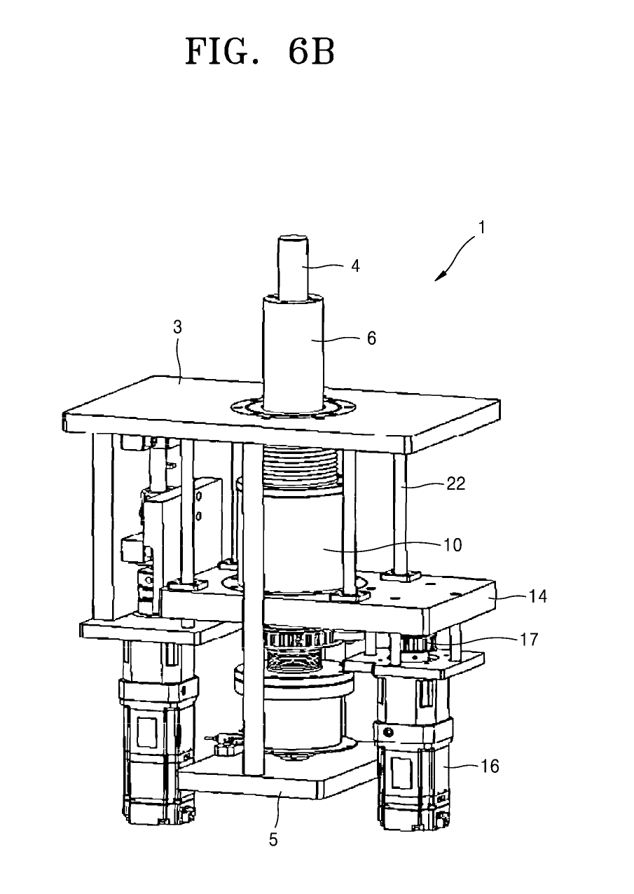

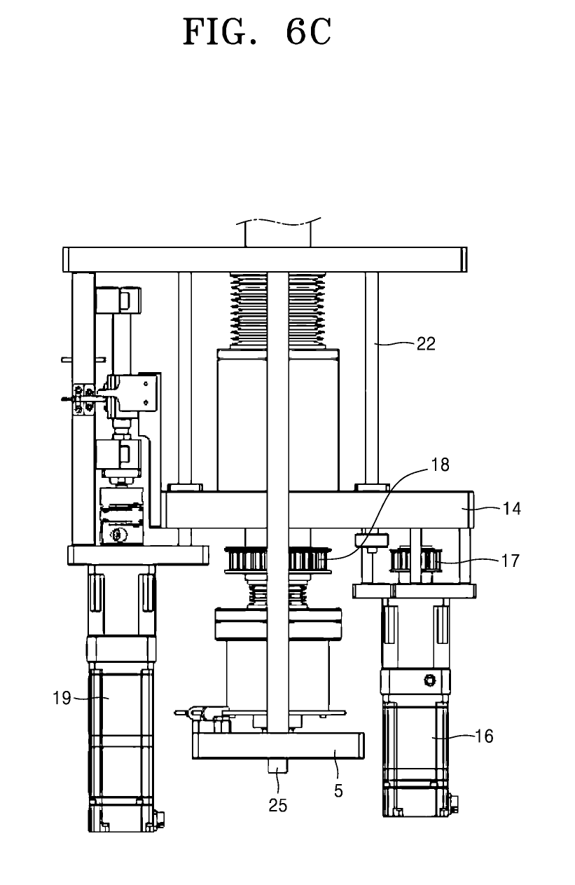

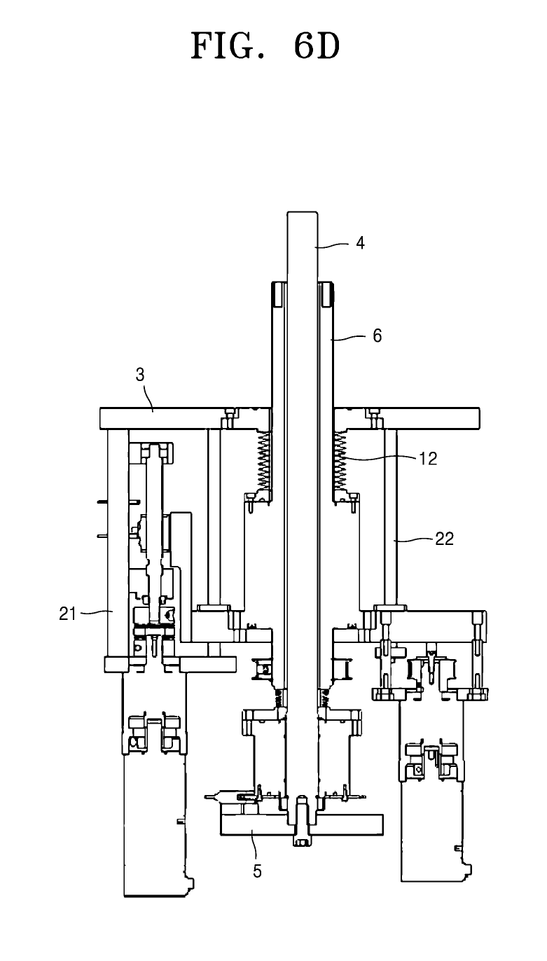

FIGS. 6A to 6D show a substrate-processing device according to example embodiments, to which the configurations of FIGS. 5A and 5B are applied. FIGS. 6A and 6B are perspective views of the substrate-processing device, FIG. 6C is a front view of the substrate-processing device, and FIG. 6D is a perspective view of the substrate-processing device. Detailed descriptions of each part of FIGS. 6A to 6D will not be given herein since they were described in FIGS. 5A and 5B.

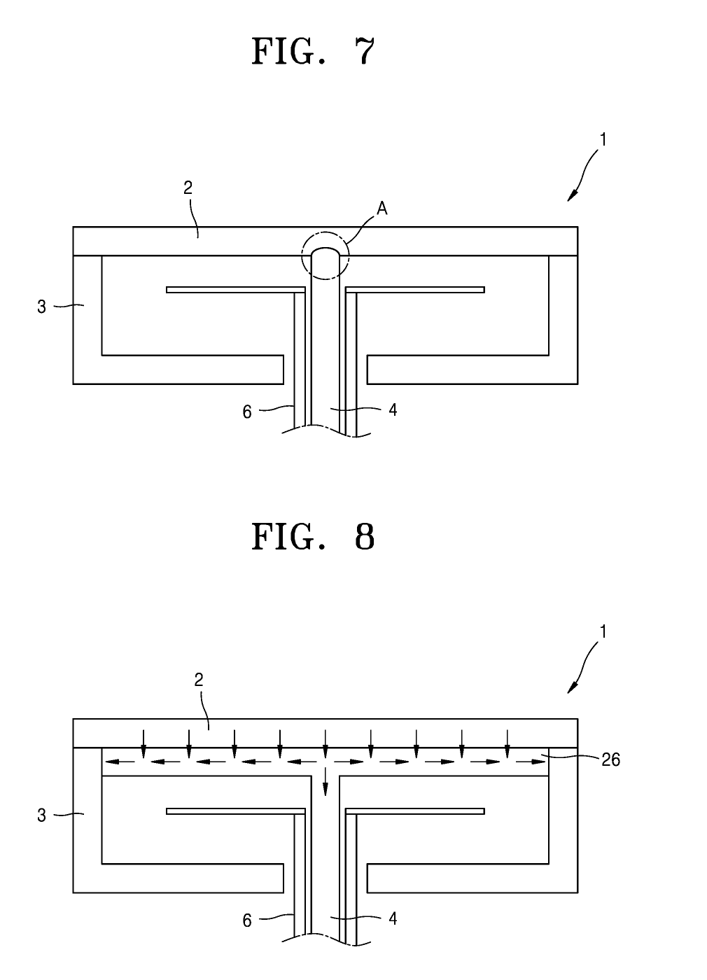

FIG. 7 is a partial enlarged view of a substrate-processing device according to example embodiments.

Referring to a dashed line region A in FIG. 7, an upper portion of the top lid support 4 in contact with the top lid 2 has a convex portion, and a lower surface of the top lid has a corresponding concave portion.

The convex portion of the top lid support 4 is coupled to the concave portion so that the top lid support 4 may be tightly fixed to the top lid 2. When the rotating shaft 6 rotates, it is possible to prevent the top lid support 4 from being shaken.

Meanwhile, a structure of the upper portion of the top lid support 4 is not limited to that shown in FIG. 7. For example, although the upper portion of the top lid support 4 is shown as having a convex portion, alternatively, a concave portion may be formed on the upper portion of the top lid support 4, and a convex portion may be formed on a portion of the top lid 2 corresponding to the concave portion. In an additional variation, an outer surface of the upper portion of the top lid support 4 has protruding protrusions, and a portion of the top lid 2 corresponding to the protrusions may have grooves into which the protrusions are inserted.

According to an additional example embodiment, a shock absorbing member is provided on a lower surface of the top lid 2 or an upper surface of the top lid support 4 so that a shock applied to the top lid support 4 when the top lid 2 touches the top lid support 4 and a shock applied to the top lid support 4 by a distortion of the top lid 2 may be reduced. The shock absorbing member may be placed, applied, or attached on the lower surface of the top lid 2 at a position corresponding to the top lid support 4. For example, the shock absorbing member may be a cushioning such as a sponge, a plastic, or the like that can absorb a shock.

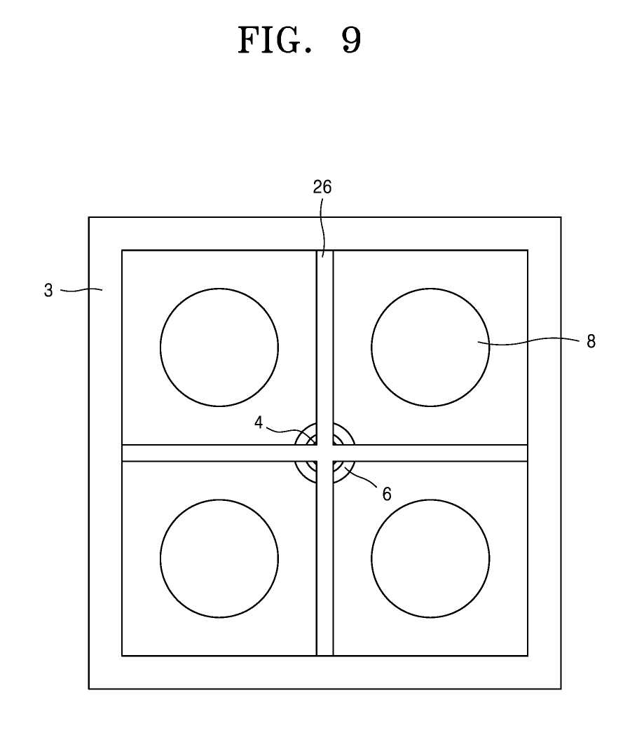

FIG. 8 is a partial cross-sectional view of a substrate-processing device, to which a top lid support frame 26 is added, according to example embodiments. FIG. 9 is a top view of the substrate-processing device of FIG. 8.

The substrate-processing device according to example embodiments may further include the top lid support frame 26 configured to support the top lid 2 across the internal space 9. In more detail, referring to FIGS. 8 and 9, the top lid support frame 26 connects the top lid support 4 to the chamber wall 3. This configuration is more effective in dispersing a load of the top lid 2, which is concentrated on the top lid support 4, into the chamber wall 3 overall and thus the increase in fatigue of the top lid support 4 and distortion thereof may be prevented. Arrows in FIG. 8 indicate that the load of the top lid 2 is dispersed through the top lid support frame 26.

The top lid support frame 26 may be mechanically connected to the top lid support 4 and/or the chamber wall 3 by screwing, fitting or the like. For example, a plurality of top lid support frames 26 may be symmetrically arranged with respect to the top lid support 4.

In FIG. 9, four top lid support frames 26 are arranged around the centered top lid support 4, but the present disclosure is not limited thereto. For example, two top lid support frames arranged symmetrically. Furthermore, the plurality of top lid support frames 26 may be symmetrically arranged around the centered top lid support 4 between the substrate supports 8 so that the top lid support frames 26 do not interfere with the substrate supports 8 and the gas supply disposed in the top lid 2 corresponding to the substrate support 8.

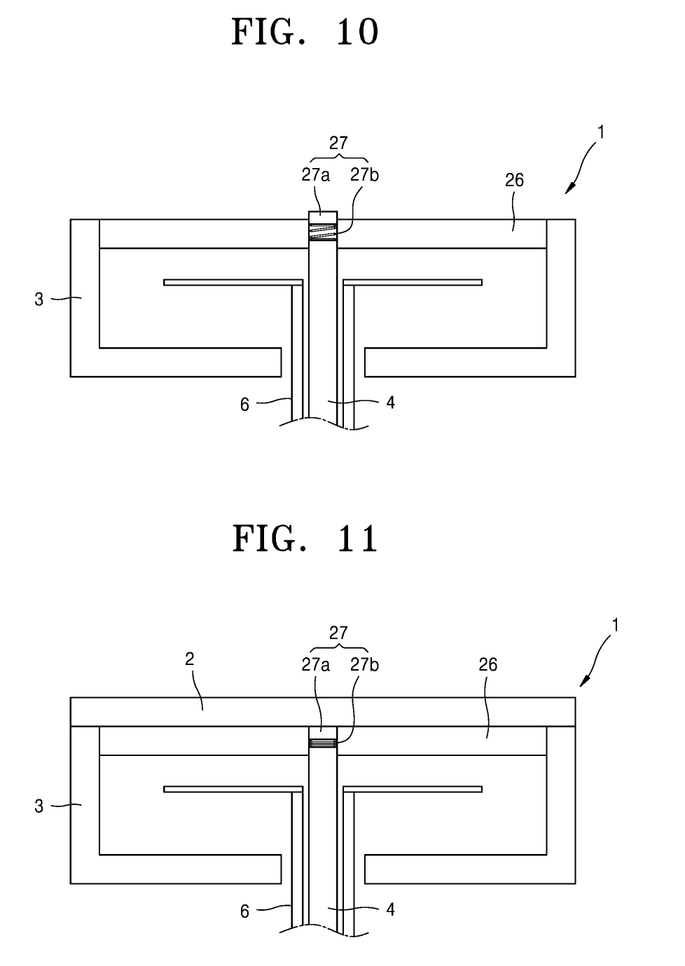

FIGS. 10 to 13 are cross-sectional views of a substrate-processing device to which an elastic portion is added, according to other example embodiments.

FIG. 10 shows a substrate-processing device in which the top lid 2 is not disposed, and FIG. 11 schematically shows an elastic portion 27 when the top lid 2 is disposed in the substrate-processing device of FIG. 10.

Referring to FIG. 10, the elastic portion 27 may be disposed on the top lid support 4. The elastic portion 27 may include a cap 27a and an elastic body 27b disposed between the cap 27a and the top lid support 4. The elastic body 27b may be implemented as at least one of a spring, fluid, and gas, or a combination thereof.

The elastic portion 27, when lifting and then lowering again the top lid 2 for maintenance of the chamber 1 and placing the top lid 2 on the chamber wall 3, may absorb an impact applied to the top lid support 4 by a load of the top lid 2. In addition, it is possible to minimize damage of the substrate-processing device which may be caused by an impact when the top lid 2 is lowered or the generation of contaminants such as particles which may occur due to the damage. By appropriately selecting the elastic body 27b, the impact caused by the top lid 2 may be more effectively controlled.

Specific example embodiments of a lifting operation of a top lid for maintenance of a chamber are described in detail in Korean Patent Application No. 10-2016-0096121.

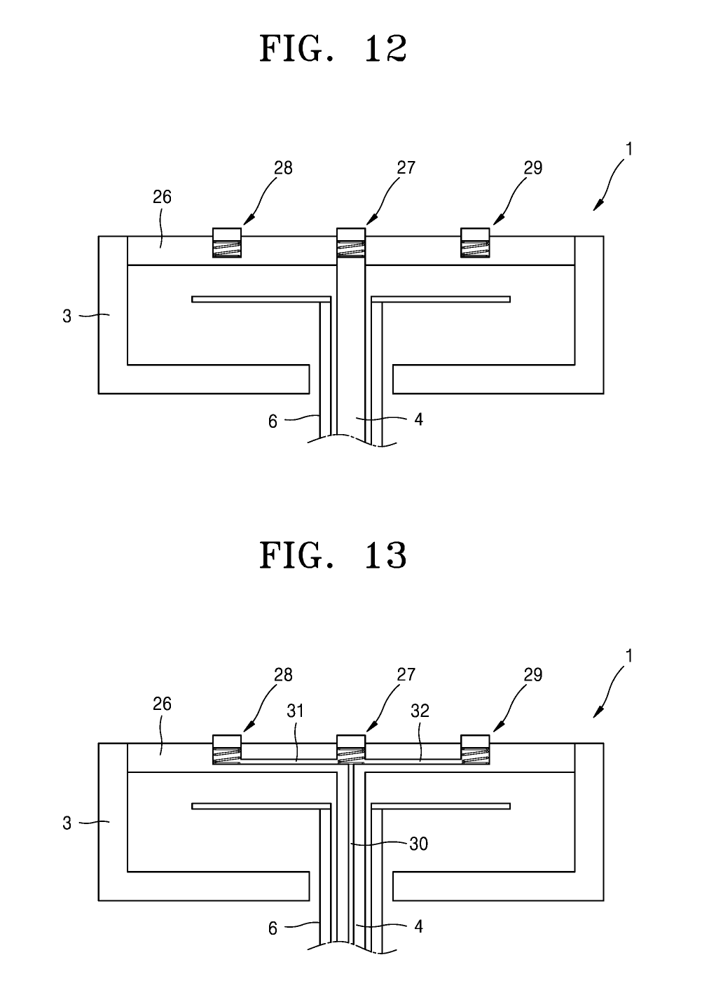

According to additional example embodiments, at least one elastic portion may be disposed on at least one surface of the top lid support 4 for supporting a top lid and/or the top lid support frame 26. For example, as shown in FIG. 12, the elastic portion 27 is disposed not only on the upper portion of the top lid support 4 but also on the top lid support frame 26 (particularly, an upper portion of the top lid support frame 26), so that the impact applied by the lifting and lowering of the top lid 2 may be more effectively absorbed or mitigated.

As described above, the impact caused by the top lid 2 may be more effectively controlled by appropriately controlling elastic pressure of the elastic portion 27, and a stable operation of the top lid support 4 and the top lid support frame 26 is easier.

To this end, according to additional example embodiments, the substrate-processing device may further include a gas or fluid supply line connected to an elastic portion and a pressure controller.

In more detail, as shown in FIG. 13, the substrate-processing device may further include fluid supply lines 30, 31, and 32 for supplying fluid or gas to the top lid support 4 and elastic portions 27, 28, and 29 of the top lid support frame 26. The fluid supply lines 30 to 32 are connected to a fluid supply (not shown) for supplying fluid, and pressure of the elastic portions 27 to 29 may be controlled by a controller (not shown) for controlling pressure. It is possible to control the speed at which the top lid 2 contacts the top lid support 4 and the top lid support frame 26 when the top lid 2 is lowered by controlling the pressure of the elastic portion 27, thereby enhancing stability during a maintenance work.

In additional example embodiments, the fluid supply lines 30 to 32 may perform a cooling function of the top lid support 4. For example, when the substrate-processing device performs a high-temperature process, a coolant may be circulated through the fluid supply lines 30 to 32, thereby preventing a thermal expansion problem of the top lid support 4. Such a fluid supply line may be implemented independently of presence of the elastic portions 27 to 29. For example, only a fluid supply line other than an elastic portion may be applied to the top lid support 150 (of FIG. 1). Accordingly, heat generated by a heater (not shown) of the substrate-processing device may be transmitted to the top lid support 4 and thermal expansion of the top lid support 4 may be prevented.

To summarize some of the above configurations, the substrate-processing device according to example embodiments may be described as follows.
The substrate-processing device includes a top lid support and/or a top lid support frame, wherein the top lid support and/or the top lid support frame may prevent the top lid from being distorted by its own weight and/or by a vacuum suction force generated by a vacuum pump and/or by thermal shock at high temperature process.
A rotating shaft of the substrate-processing device may have a hollow structure, and the top lid support may be formed in the hollow structure and extend to the top lid to support the top lid.
In order to isolate the inner space of a chamber from the outside, at least one stretchable portion and/or at least one sealing portion may be arranged around a through-hole, the rotating shaft, and the top lid support.
At least one top lid support plate fixing shaft may be provided and/or an upper portion of the top lid support may have a structure that can be fixed to the top lid in order to fix the top lid support connected to the rotating shaft when the rotating shaft is lifted and/or rotated by a lifting motor and/or a rotating motor.
The top lid support and/or the top lid support frame may include an elastic portion, and pressure of the elastic portion may be controlled to control the speed and impact at which the top lid contacts the top lid support and the top lid support frame when the top lid is lowered. This may enhance stability during a maintenance work.

The above disclosure provides a number of example embodiments and a number of exemplary advantages of a substrate-processing device including a top lid support. For the sake of brevity, only a limited number of combinations of related features have been described. It should be understood, however, that features of any example may be combined with features of any other example. Moreover, it should be understood that these advantages are non-limiting and that no particular advantage is specified nor required in any particular example embodiment.

It should be understood that example embodiments described herein should be considered in a descriptive sense only and not for purposes of limitation. Descriptions of features or aspects within each example embodiment should typically be considered as available for other similar features or aspects in other example embodiments.

While one or more example embodiments have been described with reference to the figures, it will be understood by those of ordinary skill in the art that various changes in form and details may be made therein without departing from the spirit and scope of the disclosure as defined by the following claims.

What is claimed is:

1. A substrate-processing device comprising:
a top lid;
a chamber wall including a through-hole;
a plurality of substrate supports arranged in the chamber wall;
a driving shaft penetrating through the through-hole of the chamber wall and extending between the plurality of substrate supports; and
a top lid support formed in a hollow of the driving shaft and penetrating through the through-hole to support the top lid.

2. The substrate-processing device of claim 1, further comprising:
a first plate connected to the driving shaft; and
a second plate connected to the top lid support.

3. The substrate-processing device of claim 2, wherein
the first plate is movable, and
the second plate is fixed.

4. The substrate-processing device of claim 3, further comprising:
a drive unit connected to the first plate and configured to move the driving shaft up and down.

5. The substrate-processing device of claim 3, further comprising:
a fixing shaft extending between the chamber wall and the second plate.

6. The substrate-processing device of claim 5, wherein
the top lid support and the second plate are fixed to the chamber wall by the fixing shaft.

7. The substrate-processing device of claim 2, further comprising:
a first shielding unit configured to shield a space between the chamber wall and the driving shaft; and
a second shielding unit configured to shield a space between the driving shaft and the second plate.

8. The substrate-processing device of claim 7, wherein
at least one of the first shielding unit and the second shielding unit comprises:
a stretchable portion; and
a rotation support portion connected to the stretchable portion and configured to facilitate rotation of the driving shaft.

9. A substrate-processing device comprising:
a top lid;
a chamber wall including a through-hole;
a plurality of substrate supports arranged in the chamber wall;
a driving shaft penetrating through the through-hole of the chamber wall and extending between the plurality of substrate supports;
a top lid support formed in a hollow of the driving shaft and penetrating through the through-hole to support the top lid;
a first plate connected to the driving shaft;
a second plate configured to fixedly support the top lid support;
a first shielding unit disposed between the first plate and the chamber wall;
a second shielding unit disposed between the second plate and the driving shaft;
a fixing shaft extending from the chamber wall to the second plate;
a first drive unit connected to the first plate and configured to move the driving shaft up and down; and
a second drive unit configured to rotate the driving shaft.

10. A substrate-processing device comprising:
an inner space defined by a top lid and a chamber wall;
an exhaust portion connected to the inner space;
a plurality of substrate supports arranged in the inner space;
a through-hole penetrating through a lower surface of the chamber wall and formed between the plurality of substrate supports; and
a top lid support configured to support the top lid through the through-hole.

11. The substrate-processing device of claim 10, further comprising:
a driving shaft configured to surround the top lid support through the through-hole;
a rotating motor configured to rotate the driving shaft; and
a lifting motor configured to lift the driving shaft.

12. The substrate-processing device of claim 11, further comprising:
a substrate transfer rotating arm connected to one surface of the driving shaft.

13. The substrate-processing device of claim 12, further comprising:
a first sealing portion configured to surround the driving shaft;
a second sealing portion configured to surround the top lid support;
a first bellows configured to connect the first magnetic sealing portion to the lower surface of the chamber wall; and
a second bellows configured to connect the second magnetic sealing portion to a lower surface of the driving shaft, wherein
the first magnetic sealing portion and the second magnetic sealing portion are configured to isolate the driving shaft and the top lid support from the outside.

14. The substrate-processing device of claim 13, further comprising:
a top lid support plate configured to support the top lid support; and
at least one top lid support plate fixing shaft configured to support the top lid support plate on the lower surface of the chamber wall.

15. The substrate-processing device of claim 10, wherein
an upper surface of the top lid support, which is in contact with the top lid, is curved.

16. The substrate-processing device of claim 10, further comprising:
at least one top lid support frame, wherein
the top lid support frame is connected to the top lid support and is configured to support the top lid across the inner space.

17. The substrate-processing device of claim 16, further comprising:
at least one elastic portion on at least one surface of the top lid support for supporting the top lid and the top lid support frame.

18. The substrate-processing device of claim 17, wherein
the at least one elastic portion comprises:
a cap; and
an elastic body.

19. The substrate-processing device of claim 18, wherein
the elastic body is implemented as at least one of a spring, fluid, and gas, or a combination thereof.

20. The substrate-processing device of claim 17, further comprising:
a gas or fluid supply line connected to the elastic portion; and
a pressure controller.
